(19) United States
(12) Patent Application Publication
(10) Pub. No.: US 2005/0225942 A1
(43) Pub. Date: Oct. 13, 2005

(54) Plug-in cooling device

(75) Inventor: Larry Lee, Taipei (TW)

Correspondence Address: TROXELL LAW OFFICE PLLC;SUITE 1404, 5205 LEESBURG PIKE, FALLS CHURCH, VA, 22041, US

(73) Assignee: First International Computer Inc.

(21) Appl. No.: 10/819,109

(22) Filed: Apr. 7, 2004

(51) Int. Cl. H05K 7/20

(52) U.S. Cl. 361/700

(57) ABSTRACT

A plug-in cooling device adapted to be inserted into a computer to dissipate heat from the heat sink of the internal cooling module of the mobile computer is described. A heat sink has a fan. A heat conducting block is inserted into the mobile computer to touch the heat sink of the internal cooling module of the computer and to absorb heat energy from the internal cooling module of the computer. The heat conduction connecting means is connected between one side of the heat conducting block and one side of the heat sink of the plug-in cooling device.

### BACKGROUND OF THE INVENTION

1. Field of the Invention

The present invention relates to a cooling device used to dissipate heat from a computer and, more particularly, to a plug-in cooling device that can be plugged into a mobile computer to absorb and dissipate heat energy from the internal cooling module of the mobile computer.

2. Description of the Related Art

To fit the fast processing speed of the CPU of an advanced mobile computer such as, for example, a notebook computer or tablet PC, a high-performance cooling module must be used. Because mobile computers are made lighter, thinner, shorter, and smaller, the size of the internal cooling module must be relatively reduced. However, reducing the size affects the performance of the cooling module. Due to the limitation of the performance of cooling modules, mobile computers may not be able to upgrade the CPU, or the size of mobile computers cannot be made further lighter, thinner, shorter, and smaller.

### SUMMARY OF THE INVENTION

The present invention has been accomplished under the circumstances in view. It is the main object of the present invention to provide a plug-in cooling device for mobile computer, which is externally attachable to a mobile computer to enhance the cooling performance of the internal cooling module of the mobile computer so that mobile computer designers can design lighter, thinner, shorter, and smaller mobile computers for use with a high-speed CPU. It is another object of the present invention to provide a plug-in cooling device for a mobile computer, which is provided with a heat plate for holding and heating an incense strip or cup of water.

To achieve these and other objects of the present invention, the plug-in cooling device comprises a cooling module adapted to be inserted into a computer to dissipate heat from the heat sink of the internal cooling module of the mobile computer. The cooling module of the plug-in cooling device comprises a heat sink including a fan, a heat conducting block for insertion into the mobile computer to touch the heat sink of the internal cooling module of the computer and to absorb heat energy from the internal cooling module of the computer, and a heat conduction connecting means connected between one side of the heat conducting block and one side of the heat sink of the plug-in cooling device. Further, a heat plate is extended out of the heat sink of the cooling module of the plug-in cooling device for holding and heating an incense strip or a cup of water.

### BRIEF DESCRIPTION OF THE DRAWINGS

The foregoing aspects and many of the attendant advantages of this invention will become more readily appreciated as the same becomes better understood by reference to the following detailed description when taken in conjunction with the accompanying drawings, wherein:

FIG. 1 is an exploded view of a mobile computer and a plug-in cooling device according to the present invention, showing an internal cooling device provided inside the mobile computer;

FIG. 2 is an exploded view of the computer's internal cooling device and the plug-in cooling device according to the present invention;

FIG. 3 is an assembly view of FIG. 2;

FIG. 4 is a top view of FIG. 3;

FIG. 5 is similar to FIG. 1 but shows the cooling module of the plug-in cooling device according to the present invention decorated with an ornamental shell;

FIG. 6 is similar to FIG. 1 but shows a heat plate connected to the heat sink of the plug-in cooling device of the present invention and an incense strip placed on the heat plate; and

FIG. 7 is similar to FIG. 1 but shows a heat plate connected to the heat sink of the plug-in cooling device and adapted to heat a cup of water.

### DETAILED DESCRIPTION OF THE PREFERRED EMBODIMENT

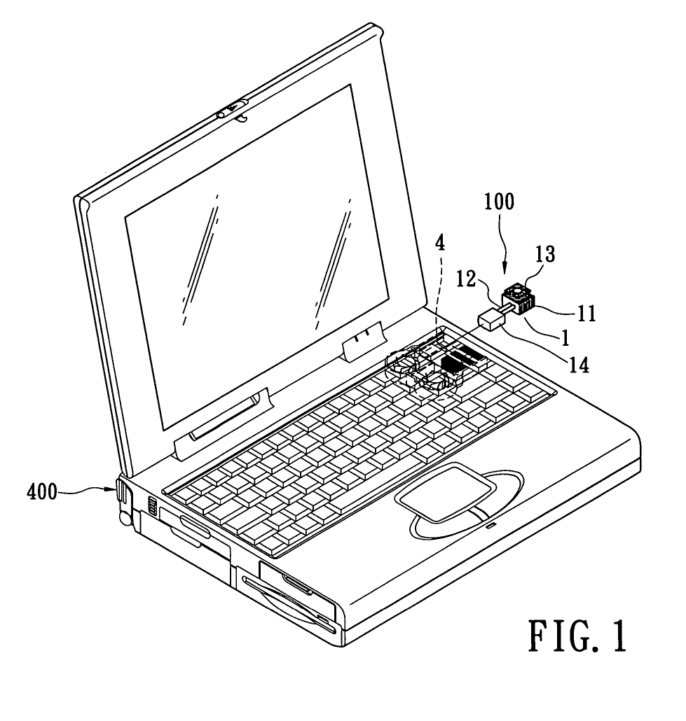

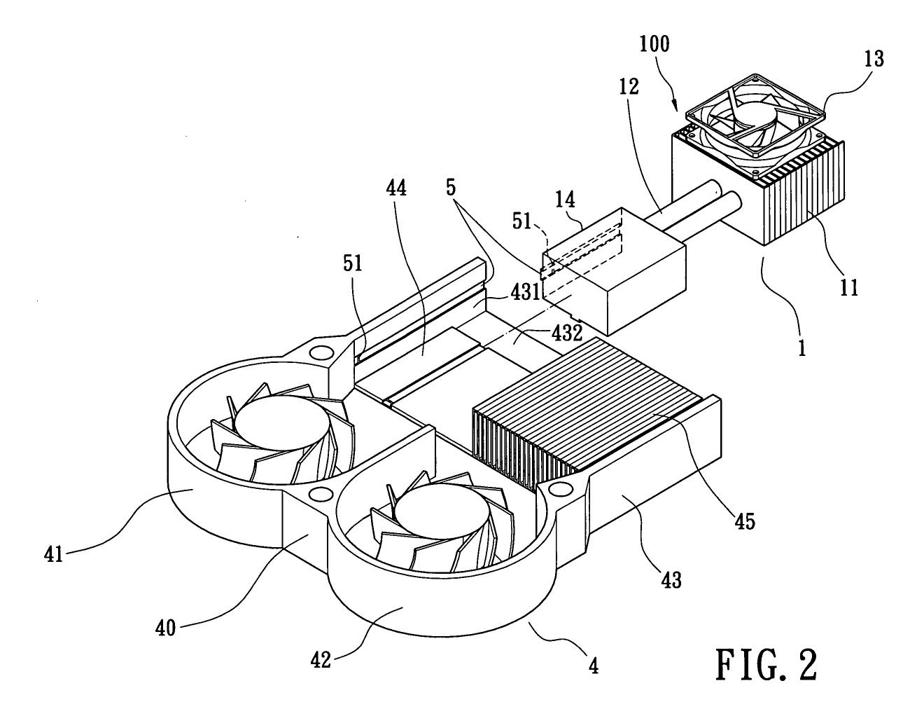

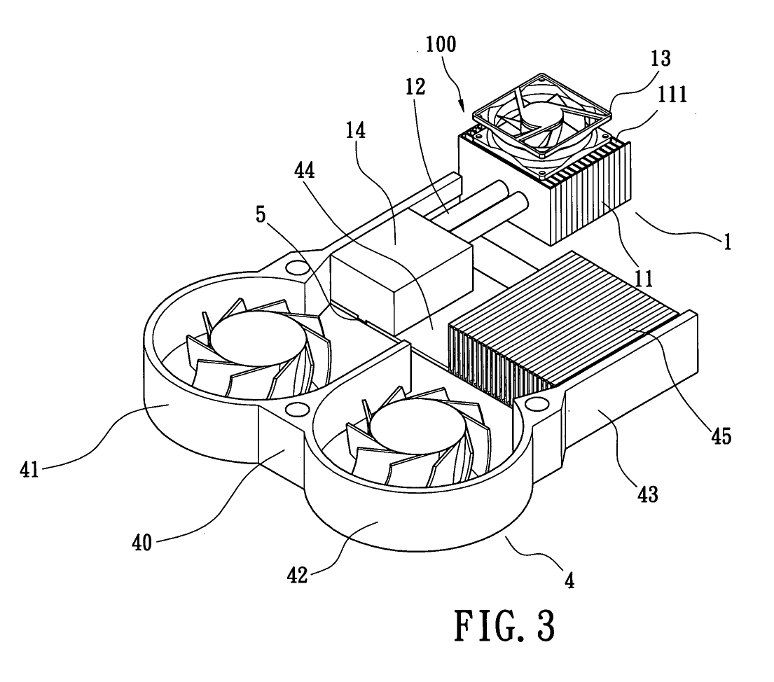

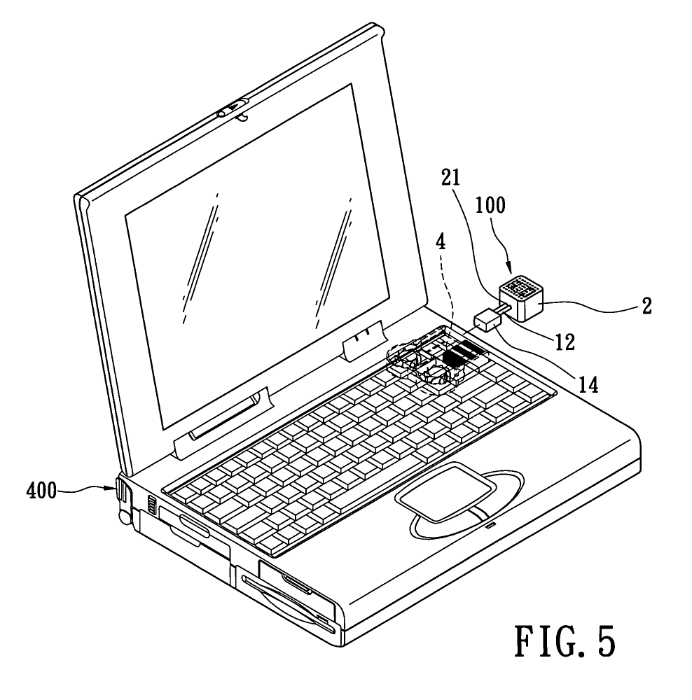

Referring to FIGS. 1-7, a plug-in cooling device 100 is generally comprised of a cooling module 1 as shown in FIGS. 1-4, and an added ornamental shell 2 and heat plate 3 as shown in FIGS. 5-7.

Referring to FIGS. 1-4, the cooling module 1 comprises a heat sink 11, a fan 13 disposed at one side of the heat sink 11, a heat conducting block 14 for insertion into a computer 400 to touch the internal cooling module 4 of the computer 400 and to absorb heat energy from the internal cooling module 4 of the computer 400, and heat conduction connecting members 12 connected between one side of the heat conducting block 14 and one side of the heat sink 11.

The heat conducting block 14 is inserted into the interior of a mobile computer (notebook computer or tablet PC) 400 to conduct heat exchange with the internal heat cooling module 4 of the computer 400. Absorbed heat energy is transmitted through the heat conduction connecting members 12 to the heat sink 11 for quick dissipation into the outside air. The heat sink 11 is preferably formed of a plurality of radiation fins. The heat conduction connecting members 12 are preferably formed of metal tubular members for the advantage of high performance in heat conductivity and heat dissipation.

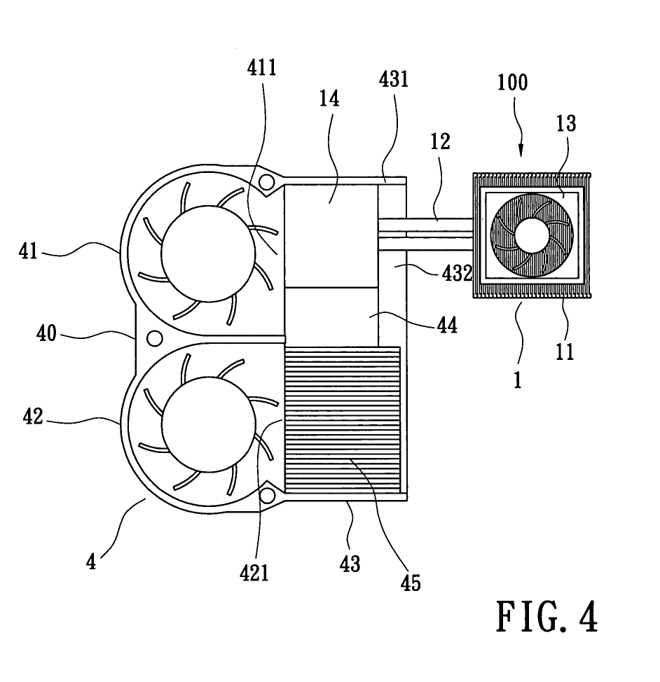

The internal cooling module 4 of the computer 400 is built inside the computer 400 and adapted to dissipate heat from the CPU of the computer 400. As illustrated, the internal cooling module 4 comprises a first fan 41 and a second fan 42 arranged parallel to each other, a first air outlet 411 and a second air outlet 421 formed in the common shell 40 of the fans 41 and 42 and respectively disposed corresponding to the fans 41 and 42 (see FIG. 4), an extension shell 43 extended from one side of the mount 40, the extension shell 43 having a bottom wall 432 and two upright sidewalls 431, a heat conduction plate 44 mounted in the extension shell 43 and extended to the air outlets 411 and 421, and a heat sink 45 mounted on the heat conduction plate 44 and aimed at the second air outlet 421 (see FIG. 4). The space defined within the extension shell 43 corresponding to the first air outlet 411 is adapted to accommodate the heat conducting block 14 of the cooling module 1 of the plug-in cooling device 100.

Further, two guiding structures 5 are provided between the heat conducting block 14 of the cooling module 1 of the plug-in cooling device 100 and the internal cooling module 4 of the computer 400. One guiding structure 5 is provided at one lateral side of the heat conducting block 14 and one upright sidewall 431 of the extension shell 43. The other guiding structure 5 is provided at the bottom side of the heat conducting block 14 and the top side of the heat conduction plate 44 (or the bottom wall 432 of the extension shell 43). By means of the guidance of the guiding structures 5, the heat conducting block 14 can easily and smoothly be inserted into the inside of the extension shell 43 and forced into contact with the heat sink 45 to transfer heat energy from the heat sink 45 of the internal cooling module 4 of the computer 400 to the heat sink 11 of the cooling module 1 of the plug-in cooling device 100. Further, a locking device 51 is provided at the end of the guiding structures 5 and adapted to lock the heat conducting block 14 to the inside of the extension shell 43. When the locking device 51 is unlocked, the plug-in cooling device 100 can easily be removed from the internal cooling module 4 of the computer 400.

Referring to FIGS. 1 and 4 again, during the operation of the computer 400, the internal cooling module 4 of the computer 400 dissipates heat from the CPU of the computer 400, and at the same time the heat conducting block 14 transfers heat energy from the heat sink 45 of the internal cooling module 4 to the heat sink 11 via the heat conduction connecting members 12 for quick dissipation into the outside air. Therefore, heat dissipation efficiency is greatly improved.

Referring to FIG. 5, the plug-in cooling device 100 further comprises an ornamental shell 2, which holds the heat sink 11 and the fan 13 on the inside (see also FIG. 1), having an opening 21 for passing the heat conduction connecting members 12 therethrough. Of course, the ornamental shell 2 has an air inlet and an outlet for circulation of air. The ornamental shell 2 decorates the cooling module 1 of the plug-in cooling device 100, making it beautiful.

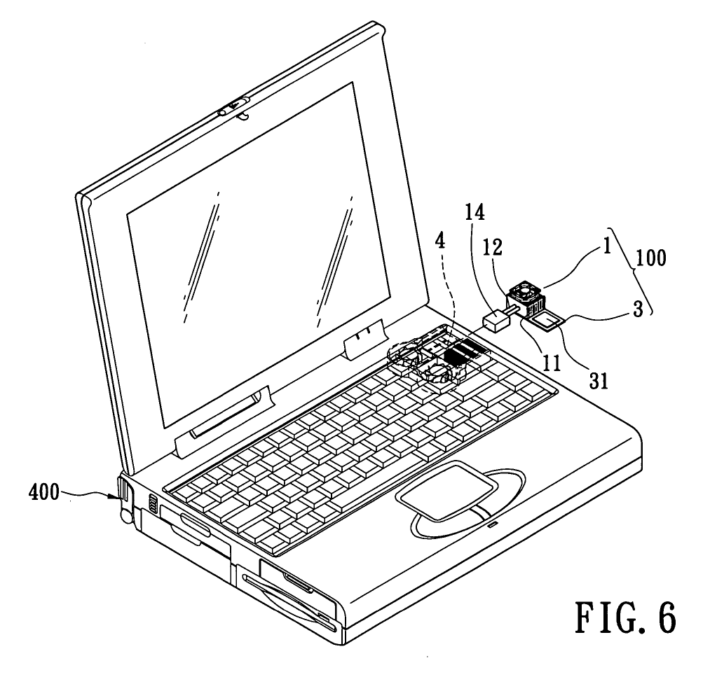

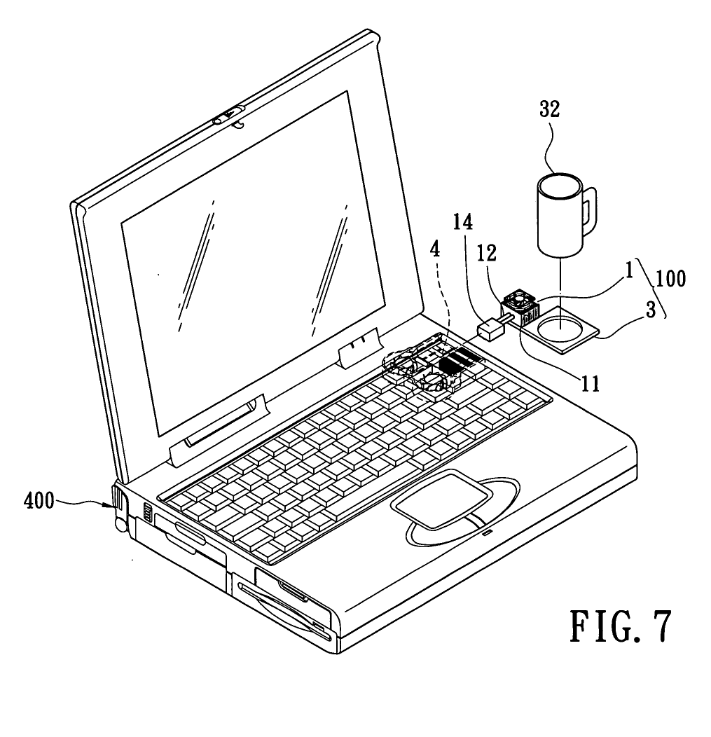

Referring to FIGS. 6 and 7, the plug-in cooling device 100 further comprises a heat plate 3 extended from one side, for example, the bottom side of the heat sink 11, and adapted to hold an incense strip 31 or a cup 32 and to transfer heat energy from the heat sink 11 to the incense strip 31 or the liquid in the cup 32, causing the incense strip 31 to release a fragrance, or keeping the liquid in the cup 32 warm.

As indicated above, the invention achieves the following advantages:

1. Because the plug-in cooling device is a mobile device externally attachable to the computer 400, it has no relation to the size of the computer 400, and therefore the computer 400 (mobile computer such as notebook computer or tablet PC) can be made with a lighter, thinner, shorter, and smaller design concept and used with a faster CPU without being constrained by the CPU cooling arrangement.

2. A heat plate 3 may be attached for holding an incense strip 31 or a cup 32 outside the computer 400, so that internal heat energy of the computer 400 can be transferred to the incense strip 31 or the liquid in the cup 32, causing the incense strip 31 to release a fragrance, or keeping the liquid in the cup 32 warm.

A prototype of a plug-in cooling device has been constructed with the features of the annexed drawings of FIGS. 1-8. The plug-in cooling device functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

1. A plug-in cooling device comprising a cooling module to be inserted into a computer to dissipate heat from the heat sink of the internal cooling module of said mobile computer, the cooling module of said plug-in cooling device comprising a heat sink, a fan disposed at one side of said heat sink, a heat conducting block for insertion into said mobile computer to touch the heat sink of the internal cooling module of said computer and to absorb heat energy from the internal cooling module of said computer, and a heat conduction connecting means connected between one side of said heat conducting block and one side of the heat sink of the cooling module of said plug-in cooling device.

2. The plug-in cooling device as claimed in claim 1, further comprising an ornamental shell covered the cooling module of said plug-in cooling device, said ornamental shell having an opening for the passing of said heat conduction connecting means.

3. The plug-in cooling device as claimed in claim 3 further comprising a heat plate extended out of one side of the heat sink of the cooling module of said plug-in cooling device.

4. The plug-in cooling device as claimed in claim 3 wherein said heat plate is adapted to hold and heat an incense strip.

5. The plug-in cooling device as claimed in claim 3, wherein said heat plate is adapted to hold and heat a cup.

6. The plug-in cooling device as claimed in claim 3, further comprising an ornamental shell covering the cooling module of said plug-in cooling device, said ornamental shell having openings for enabling said heat conduction connecting means and said heat plate to be extended out of said ornamental shell.

7. The plug-in cooling device as claimed in claim 1, further comprising a guide means provided between the heat conduction block of said plug-in cooling device and the heat sink of said internal cooling module and adapted to guide said heat conduction block into contact with the heat sink of said internal cooling module.

8. The plug-in cooling device as claimed in claim 7, further comprising a lock means provided in said guide means and adapted to lock said heat conduction block to the heat sink of said internal cooling module.
